(19) United States
(12) Patent Application Publication
(10) Pub. No.: US 2025/0389935 A1
(43) Pub. Date: Dec. 25, 2025

(54) OPTICAL DEVICES THAT INCLUDE AN APERTURE ALIGNED WITH A LENS

(71) Applicant: NILT Switzerland GmbH, Horgen (CH)

(72) Inventors: Martin Balimann, Zurich (CH); Niklas Hansson, Askim (SE); Stefano Atella, Zurich (CH)

(21) Appl. No.: 18/878,460

(22) PCT Filed: Jun. 27, 2023
(86) PCT No.: PCT/EP2023/067514

§ 371 Date: Dec. 23, 2024

Related U.S. Application Data
(60) Provisional application No. 63/357,153, filed on Jun. 30, 2022.

(51) Int. Cl. G02B 13/00; G02B 5/00; H10F 39/00

(52) U.S. Cl. CPC G02B 13/0085; G02B 5/005; H10F 39/8063

(57) ABSTRACT

The present disclosure describes optical devices that include an aperture aligned with a lens. Optoelectronic assemblies and methods of fabricating the optical devices are described as well.

### FIELD OF THE DISCLOSURE

The present disclosure relates to optical devices that include an aperture aligned with a lens.

### BACKGROUND

Wafer-level stacking sometimes is used to align an optical aperture on a glass substrate to a lens. In some instances, a structured glass spacer wafer provides a specified separation between the aperture and the lens. However, using such glass wafers and substrates that intersect the optical path of incoming or outgoing light may result in a relatively large total track length (TTL), whereas a smaller TTL may be desirable for some applications.

### SUMMARY

The present disclosure describes optical devices that include an aperture aligned with a lens. Optoelectronic assemblies that include such an optical device, and methods of fabricating the optical devices and assemblies, are described as well.

For example, in one aspect, the present disclosure describes an apparatus that includes an optical aperture defined by a layer of metal disposed on a spacer, and a lens disposed on a support that is attached to the spacer, wherein the lens is aligned with the optical aperture. A thickness of the spacer in a region that is between the lens and the optical aperture is less than a thickness of the spacer at its outer periphery.

Some implementations include one or more of the following features. For example, in some implementations, the support has a first surface, and a second surface on an opposite side of the support, wherein the first surface is closer to the optical aperture than the second surface, the lens is disposed on the second surface, and a thickness of the support in a region disposed between the lens and the optical aperture is less than a thickness of the support at its outer periphery. In some implementations, the support has a first surface and a second surface on an opposite side of the support, wherein the first surface is closer to the optical aperture than the second surface, the lens being disposed on the first surface, and a thickness of the support in a region disposed directly below the lens is less than a thickness of the support at its outer periphery.

In some implementations, at least a portion of an optical path between the optical aperture and the lens is air. In some implementations, the spacer is composed of glass, and/or the layer of metal is composed of black chrome.

In some implementations, the lens includes a meta-optical element. In some cases, the apparatus includes an active optoelectronic component, and a lens holder to maintain the lens in place over the active optoelectronic component.

The present disclosure also describes an apparatus that includes a spacer having an opening extending through the spacer, wherein the opening has a first end that has a first diameter, and a second end that has a second diameter larger than the first diameter. The spacer is composed of a material that is substantially opaque to an application wavelength. A lens is disposed on a support that is attached to the spacer, wherein the lens is aligned with the opening in the spacer.

Some implementations include one or more of the following features. For example, in some implementations, the spacer is composed of a plastic (e.g., acetal resin) or a semi-crystalline thermoplastic. In some implementations, the opening is cone shaped or pyramid shaped.

The apparatus can includes, for example, a layer of metal disposed on the spacer and defining an optical aperture. In some implementations, the lens includes a meta-optical element.

In some implementations, an outer perimeter of the spacer has at least one step, and in some cases, the outer perimeter of the spacer has at least two steps.

In some implementations, the apparatus includes an active optoelectronic component, and a lens holder to maintain the lens in place over the active optoelectronic component.

The present disclosure also describes an apparatus that includes an optical aperture, a lens disposed on a support and aligned with the optical aperture, and a spacer separating the lens from the optical aperture. The spacer has an opening extending from a first end that is closer to the aperture to a second end that is closer to the lens. An outer perimeter of the spacer has a plurality of steps.

Some implementations include one or more of the following features. For example, in some implementations, an outer diameter of the spacer at a location of a first one of the steps differs from an outer diameter of the spacer at a location of a second one of the steps. In some implementations, the spacer is composed of a material that is substantially opaque to an application wavelength. For example, in some implementations, the spacer can be composed of a plastic (e.g., acetal resin) or a semi-crystalline thermoplastic. In some implementations, the opening is cone shaped or pyramid shaped.

In some implementations, the apparatus includes an active optoelectronic component, and a lens holder to maintain the lens in place over the active optoelectronic component. A first one of the steps at the outer periphery of the spacer is configured so that the spacer is supported by the lens holder. In some implementations, a second one of the steps at the periphery of the spacer is configured to allow a gripper to hold the spacer for active alignment with the active optoelectronic component.

Some implementations include one of more of the following advantages. For example, in some implementations, the optical device can have a smaller z-height and/or a smaller total track length. Further, using an opaque spacer in some implementations can facilitate absorption of stray light, including light incident at high angles and/or light propagating by total internal reflection in the lens substrate. In some instances, the fabrication techniques can help reduce overall manufacturing complexity and/or costs.

Other aspects, features and advantages will be readily apparent form the following detailed description, the accompanying drawings, and the claims.

### BRIEF DESCRIPTION OF THE DRAWINGS

FIGS. 1A-1C illustrate stages in the manufacture of optical devices using a transparent substrate as a spacer in wafer-level stacking.

FIG. 2 illustrates another example of optical devices that have a transparent substrate as a spacer.

FIG. 3 illustrates yet another example of optical devices that have a transparent substrate as a spacer.

FIG. 4A illustrates a stage in the manufacture of optical devices using an opaque wafer as a spacer in wafer-level stacking.

FIG. 4B is a top view of the opaque wafer in FIG. 4A.

FIG. 4C is an example of an optical device that includes an opaque spacer.

FIG. 5 illustrates another example of a stage in the manufacture of optical devices using an opaque wafer as a spacer in wafer-level stacking.

FIG. 6 is an example of an optical device that includes notches or other steps in a spacer that can facilitate integrating the device into an optoelectronic assembly.

FIG. 7 illustrates an example of an optoelectronic module including the optical device of FIG. 6.

FIG. 8 illustrates another example of an optoelectronic module.

FIG. 9 illustrates a further example of an optoelectronic module.

FIGS. 10A-10D illustrate various stages in the manufacture of an optical device.

### DETAILED DESCRIPTION

The present disclosure describes optical devices that includes an optical aperture aligned to a lens, as well as assemblies incorporating one or more such optical devices. Some of the example implementations described below refer to meta-optical elements (MOEs) as an example of lenses. However, the devices and techniques described in the present disclosure can be used with other types of lenses (e.g., diffractive optical elements (DOEs)) as well.

In one aspect, the disclosure describes techniques for forming optical devices in which the amount of air in the optical pathway can be increased and/or the amount of glass (or other material such as plastic that has an index of refraction greater than 1 at the application wavelength) in the optical pathway can be decreased relative to other arrangements, thereby facilitating enhanced or improved optical performance. In some instances, the overall z-height of the optical device can be reduced, the TTL can be reduced, and/or the amount of stray light can be reduced.

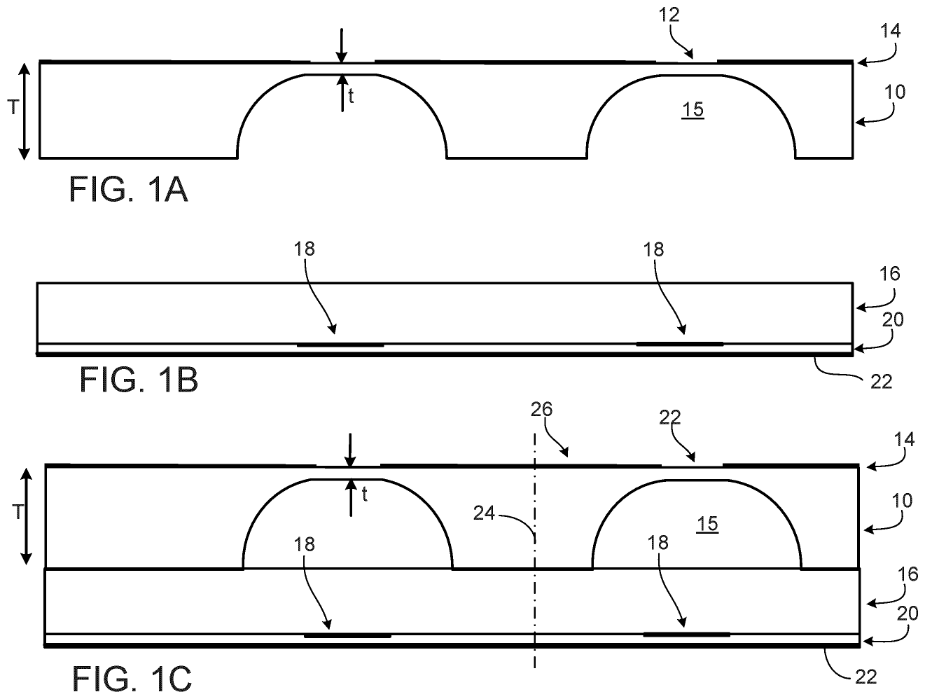

In accordance with some implementations, which can be used, for example, in wafer-level stacking techniques, a first transparent (e.g., glass) substrate is used as a carrier for apertures defined by a thin layer of metal (e.g., black chrome), and a second wafer substrate serves as a carrier for the lenses (e.g., MOEs). The thickness of at least one of the first glass substrate or the second wafer substrate can be reduced, for example, by isotropic etching, so as to increase the amount of air in the optical pathway of the optical device. FIGS. 1A-1C illustrate a first example.

As shown in FIG. 1A, a first transparent (e.g., glass) substrate 10 includes apertures 12 defined, for example, by black chrome 14 on the surface of the glass substrate. The first substrate 10 is transparent to the intended application wavelength, or range of wavelengths (e.g., near infra-red (IR), IR, or visible) for the device

The overall thickness (T) of the first glass substrate 10 is reduced, for example, by isotropic etching, in the area 15 below each of the apertures 12. Thus, the thickness (t) of the first glass substrate in the areas 15 directly below the apertures 12 can be significantly less than the overall thickness (T). In some instances the thickness (t) of the first glass substrate in the areas 15 directly below the apertures 12 may be as small as a few tenths of a micron.

FIG. 1B shows an example of a second wafer substrate 16 that includes MOEs 18 on one side. The wafer substrate 16 can be composed, for example, of glass. The MOEs 18 may be encapsulated by an encapsulant 20 (e.g., a resin), and an anti-reflective coating (ARC) 22 may be provided over the encapsulant to reduce reflections and thereby increasing transmission efficiency.

As indicated by FIG. 1C, the first glass substrate 10 and the second wafer substrate 16 are attached to one another, for example, by wafer-level stacking so that each aperture 12 is aligned with a respective one of the MOEs 18. The first glass substrate 10 serves as a spacer that separates each aperture 12 from an associated MOE 18 by a specified distance. The substrates 10, 16 can be attached to one another, for example, using an adhesive. The stack then can be separated, for example by dicing along lines 24, into individual optical devices 26. Each resulting optical device 26 includes an aperture 12 aligned with a MOE 18. A glass spacer separates the MOE from the aperture, wherein the thickness of the portion of the glass spacer between the MOE and the aperture is significantly less than the overall thickness of the glass spacer.

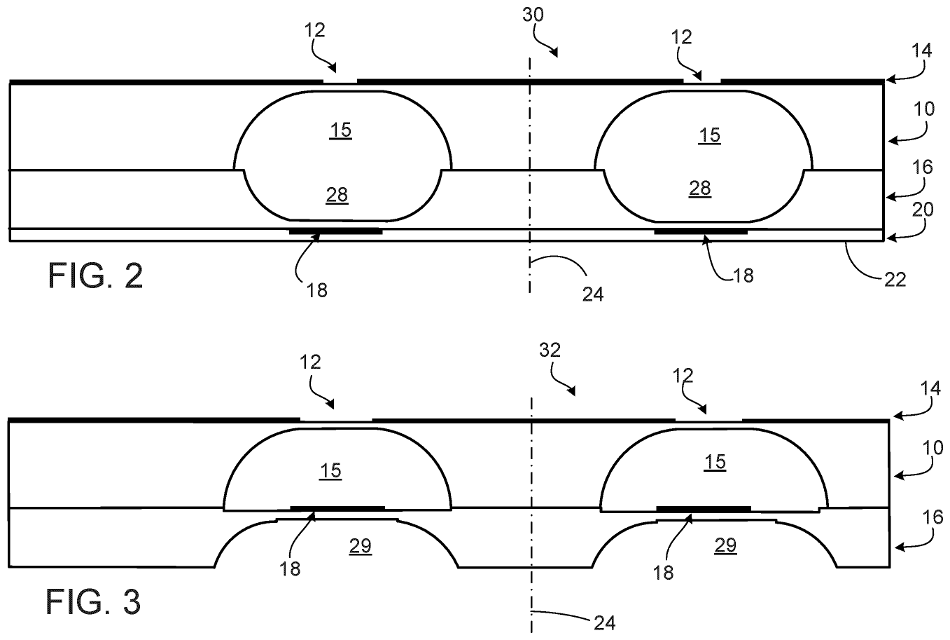

FIG. 2 illustrates a second example, in which, prior to attaching the substrates 10, 16 to one another, areas 28 of the second wafer substrate 16 directly above each of the MOEs 18 are etched away, for example by isotropic etching, so as to reduce the thickness of the wafer substrate 16 directly above each MOE. Thus, the thickness of the wafer substrate 16 directly over the MOEs 18 can be significantly less than the overall thickness of the second wafer substrate. This technique can provide the optical benefits of a thin wafer (e.g., increasing the amount of air in the optical path) as well as the benefits of robust manufacturing. Thinning of the wafer substrate 16 can be performed instead of, or in addition, to thinning of the glass substrate 10 described above. The stack can be separated, for example by dicing along lines 24, into individual optical devices 30.

As illustrated in the example of FIG. 3, in some cases, the thickness of the second wafer substrate 16 can be reduced in areas 29 below, rather than above, the MOEs 18. This allows the MOEs 18 to be located on the side of the second wafer substrate 16 that is closer to the first glass substrate 10. In some instances, this arrangement may allow an encapsulant surrounding the MOEs 18 to be omitted as the MOEs are protected within an area bounded by the two substrates 10, 16. The stack can be separated, for example by dicing along lines 24, into individual optical devices 32.

As the refractive index of the air is less than that of substrates, each of the implementations of FIGS. 1C, 2 and 3 can help reduce the TTL of the optical device. In some implementations, a small, compact device can be achieved.

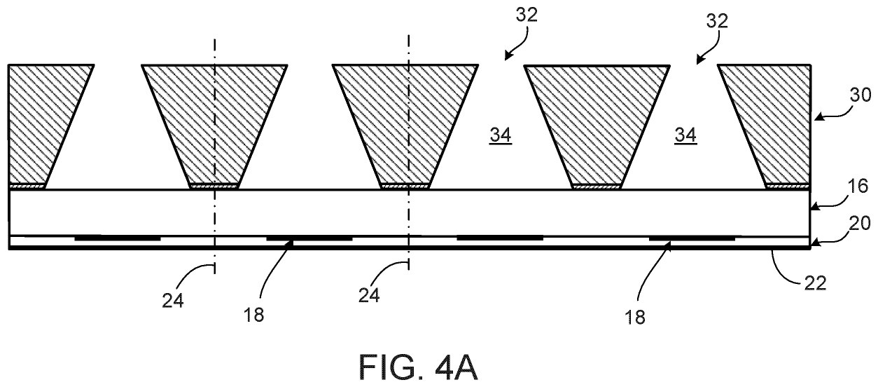

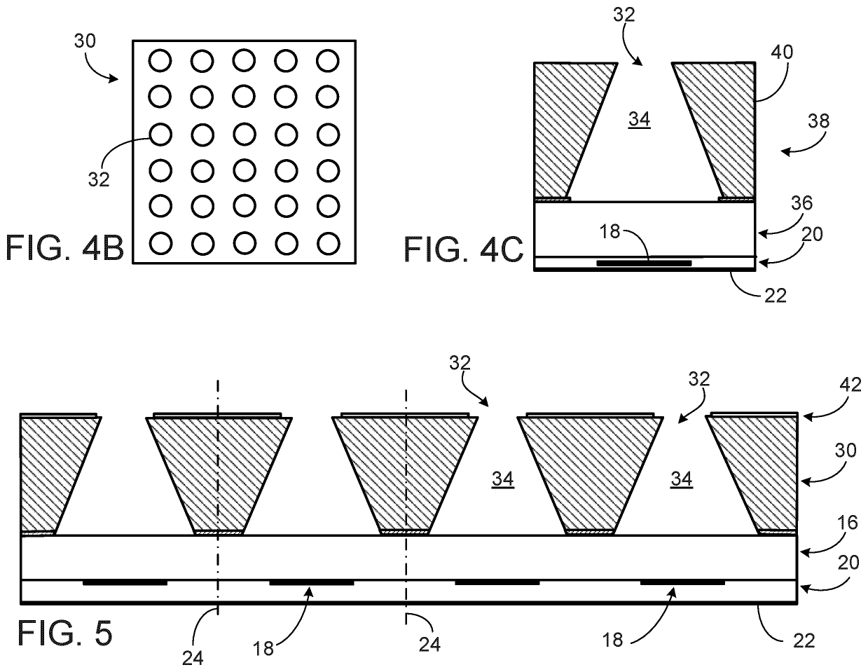

The use of a glass substrate 10 as the carrier for the apertures 12 may result, in some instances, in reflections or stray light, which may be undesirable for some applications. FIGS. 4A-4B illustrate an implementation that uses an opaque wafer 30 as a spacer instead of the glass substrate 10 of FIGS. 1C, 2 and 3. Preferably, the wafer 30 is composed of a material that is substantially opaque to the application wavelength (or range of wavelengths) and includes conical or other openings 34 extending through the wafer. In this case, the narrow side (i.e., the free end) of the openings 34 in the wafer 30 can define optical apertures 32 that are aligned, respectively, with the MOEs 18 in the wafer substrate 16. The wafer 30 also can serve as a spacer that separates the apertures 32 from the associated MOEs 18 by a specified distance.

The opaque wafer 30 can be composed, for example, of a plastic material such as an acetal resin (e.g., polyoxymethylene (POM)) or a semi-crystalline thermoplastic (e.g., polyether ether ketone (PEEK)). Other materials may be used for some implementations. The wafer 30 can be machined or molded to form the openings 34 such that the smaller diameter is sized to correspond to the target diameter for the optical apertures 32. For some optical systems, the aperture diameter is smaller than the diameter of the MOE 18, and the openings 34 can have a conical shape such that the apertures 32 are circular. In other implementations, the openings 34 can have a pyramid shape such that the apertures 32 are square. Square-shaped apertures may be advantageous, for example, for array cameras that include a single sensor that produces multiple images that can be stitched together. For some consumer applications, the aperture diameter is in the range of 0.3-1 mm, and the diameter of the lens (i.e., the MOE 18) is in the range of 1-3 mm. The distance between an MOE 18 and the associated aperture 32 is equal to the thickness of the wafer 30 and can fall within a range, for example, of 0.3-2 mm. Other implementations may have different values for the foregoing dimensions.

The wafer stack of FIG. 4A can be separated (e.g., by dicing) into individual optical devices 38 (see FIG. 4C), each of which includes an aperture 32 aligned with a MOE 18 that is on a glass or other support 36, where an opaque spacer 40 defines the aperture and separates the MOE 18 from the aperture.

Various advantages can be achieved in some implementations of the optical device of FIG. 4C. For example, as no top glass is needed to carry the aperture, the optical device can have a smaller z-height and a smaller TTL in some cases. Further, using an opaque spacer 30 can facilitate absorption of stray light, including light incident at high angles and/or light propagating by total internal reflection in the MOE substrate. In some instances, the foregoing techniques can help reduce overall manufacturing complexity and costs. In particular, as the opaque wafer 30 with openings 34 serves as both a spacer wafer and an aperture substrate, separate wafers for these purposes are needed. Also, in some cases, the foregoing techniques can help reduce the number of assembly steps and tolerance stack-up.

In some implementations, thin portions of the substantially opaque wafer 30 (e.g., near the boundary of the aperture) may allow some light at the application wavelength to pass through. To reduce or eliminate the transmission of such light through the wafer 30, the apertures can be defined, for example, by a thin layer 42 of a metal (e.g., a black chrome coating) on the surface of the wafer 30, as shown in FIG. 5. In this case, the diameter of the openings 34 at the end near the optical apertures can be slightly smaller than the target diameter for the optical apertures 32. After separating the wafer stack into individual optical devices, the resulting optical devices will be similar to the optical device 38 of FIG. 4C, but will also include a thin layer of black chrome on the surface of the spacer 40 to define the aperture.

In some implementations, instead of wafer level fabrication and stacking, a substantially opaque wafer 30 with the openings 34 for the apertures can be separated (e.g., by dicing) into individual spacers, each of which then is aligned and placed (e.g., by a pick and place tool) for attachment over a respective MOE 18 on the wafer substrate 16. Further, in some implementations, individual spacers 40 having a conical or pyramid-shaped opening 34 can be fabricated, for example, by injection molding and then can be aligned and placed (e.g., by a pick and place tool) for attachment over a respective MOE 18 on the wafer substrate 16. Molding techniques can, in some cases, be relatively inexpensive and precise, and may allow more degrees of freedom for implementing features on the sidewalls to facilitate assembly.

In some implementations, a wafer substrate 16 that includes the MOEs 18 can be separated (e.g., by dicing) into individual units, each of which includes an MOE, and then an individual spacer 40 having a conical or pyramid-shaped opening 34 can be aligned and placed (e.g., by a pick and place tool) for attachment over the MOE 18.

Any of the optical devices described above (e.g., 26 of FIG. 1C, or 38 of FIG. 4C) can be integrated into an optoelectronic assembly, such as a light sensing or light emitting module. Such modules can include, for example, an active optoelectronic component (e.g., an image sensor) disposed so that light entering the module through the aperture passes through the MOE before being incident on the image sensor. The optical device, which includes the MOE, can be placed into a lens holder and actively aligned with the image sensor before being fixed in place over the image sensor. In some instances, the active optoelectronic component can be a light emitter (e.g., a vertical cavity surface emitting laser (VCSEL) or light emitting diode).

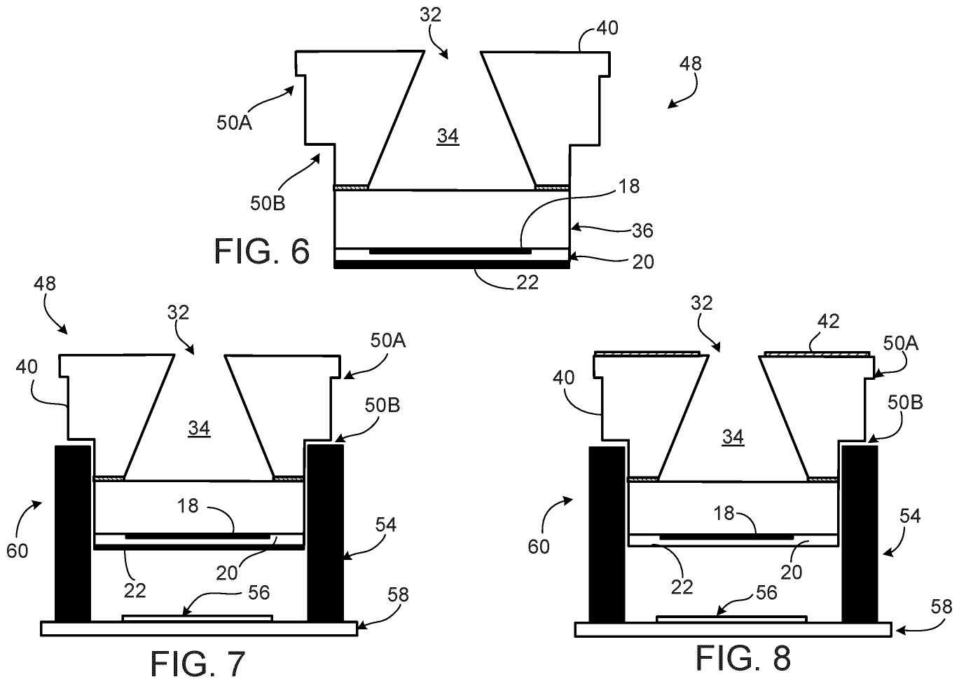

In accordance with some implementations, additional features can be provided to the optical device to facilitate assembly of the device into an optoelectronic assembly. For example, notches can be provided for the gripper of an active alignment tool to hold the optical device and align it with respect to an active optoelectronic component (e.g., an image sensor, VCSEL, or diode). As illustrated in FIG. 6, for example, diced steps (e.g., notches) 50A, 50B can be provided about the outer perimeter of the spacer 40 of an optical device 48. The notches 50A, 50B can be formed, for example, by dicing the plastic or other material of the spacer 40. The outer diameter of the spacer at a location of one of the steps 50A differs from an outer diameter of the spacer at a location of the other one of the steps 50B. For implementations in which the opaque spacer is produced by molding, the notches and other features (e.g., threads) can be formed during the molding process. Further, molding techniques can be used to produce spacers having an outer perimeter that is non-rectangular (e.g., circular). For implementations in which single round, opaque spacers are attached, for example, by pick-and-place techniques to a lens wafer 36, the overall wafer can subsequently be separated by laser cutting so as to produce round (or freeform) optical devices. Such optical devices can be designed to fit into round mounts that are sometimes found, for example, in cameras.

FIG. 7 illustrates an example of an optoelectronic module 60 that includes the optical device 48 of FIG. 6. As illustrated in FIG. 7, the notches 50A, 50B can be used to facilitate placing the device 48 into a lens holder 54, as well as active alignment of the device 48 with an image sensor 56 or other optoelectronic component mounted, for example, on a printed circuit board (PCB) 58. The upper notch 50A can allow a gripper to hold the optical device 48 for active alignment with the image sensor 56 or other optoelectronic component. The lower notch 50B allows the optical device 48 to be supported by an upper surface of the lens holder 54. Once the optical device 48 is properly aligned, the spacer 40 can be attached to the lens holder 54, for example, by an adhesive applied at the notch 50B. Preferably the lens holder 54 is composed of a light-tight material to help keep stray light out of the module 60. The foregoing combination of features can, in some implementations, provide a compact module with little stray light. In particular, the combination of the outer sidewall(s) of the lens holder 54 and the outer sidewall(s) of the spacer 40 form a substantially continuous, light-tight barrier to light entering the module 60 through the sidewalls. In some cases, as shown in FIG. 8, a thin layer 42 of a metal (e.g., a black chrome coating) can be provided on the surface upper surface of the spacer 40 to define the aperture 32 and further reduce or eliminate the transmission of light through the spacer.

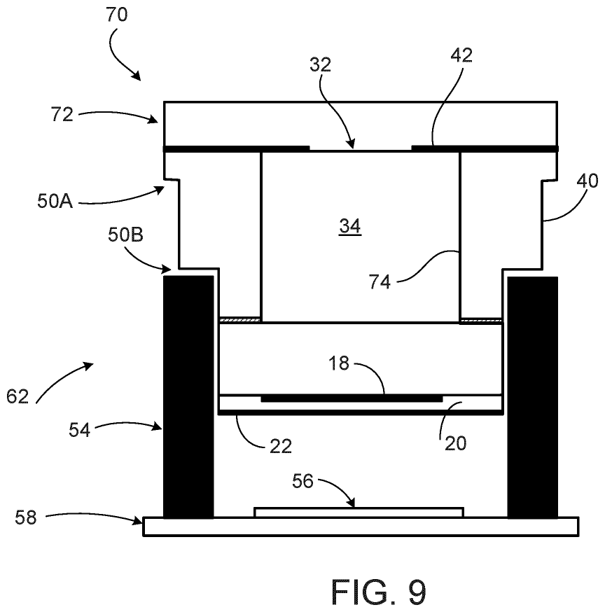

As shown in FIG. 9, in some implementations, steps (e.g., notches) 50A, 50B can be provided about the outer perimeter of the opaque spacer 40 of an optical device 70 that includes an aperture 32 defined by a thin layer 42 of metal (e.g., a black chrome coating) on a glass substrate 72, and/or in which the opening 34 in the spacer 40 below the aperture 32 has substantially vertical sidewalls 74 rather than slanted sidewalls.

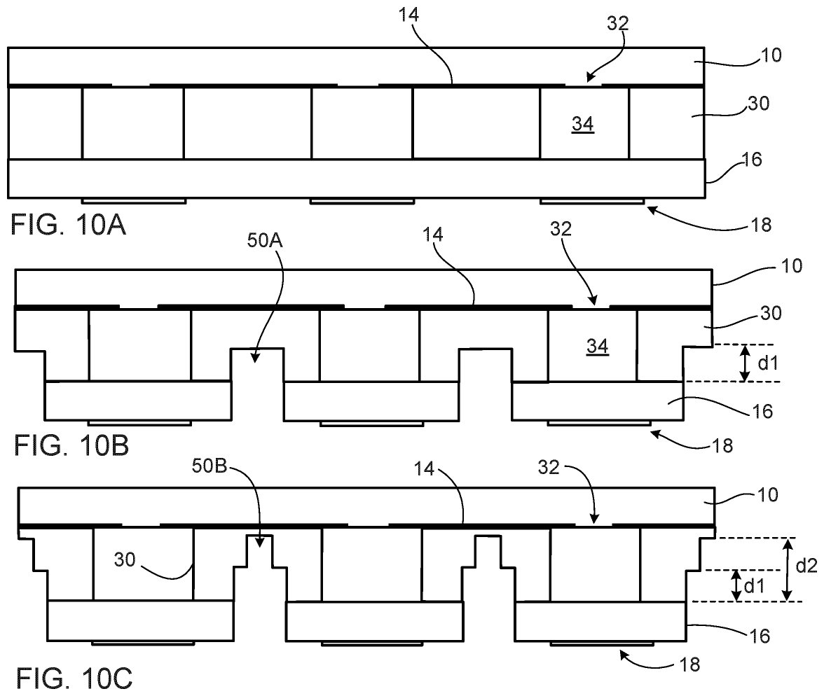

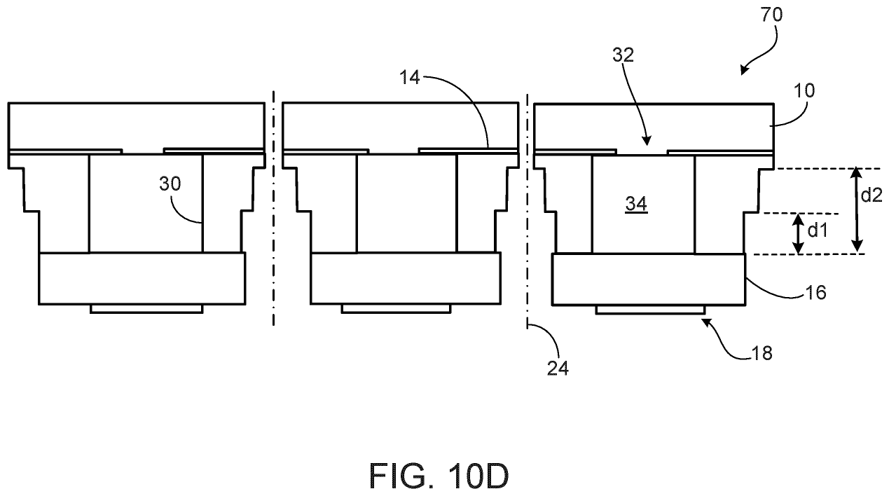

FIGS. 10A-10C illustrate stages in an example of the wafer-level manufacture of optical devices 70 of FIG. 9. FIG. 10A shows a stage that includes several substrates stacked and attached to one another. In particular, an opaque (e.g., plastic) spacer wafer 30 is attached to a first side of a lens wafer 16 that includes lenses (e.g., MOEs) 18 on one or more of its surfaces. Although the illustrated example shows the lenses 18 on an outer surface of the lens wafer 16, in some implementations, the lenses may also, or instead, be present on the opposite surface of the lens wafer. A transparent (e.g., glass) substrate 10 that includes apertures 32 defined by a thin layer 14 of metal (e.g., black chrome) on the surface of the glass substrate is attached to the opposite side of the lens wafer 16. In some instances, optical apertures may be present on other surfaces of the substrate 10 or the wafer 16. Then, as indicated by FIG. 10B, a first dicing operation is performed from the backside of the lens wafer 16. The first dicing operation penetrates through the lens wafer 16 and partially into the spacer wafer 30 to form first steps (e.g., notches) 50A in the spacer wafer 30 to a first depth d1. Next, as indicated by FIG. 10C, a second dicing operation is performed to extend a portion of each first notch deeper in to the spacer wafer 30. That is, the second dicing operation forms second steps (e.g., notches) 50B in the spacer wafer 30 to a second depth d2. Then, as indicated by FIG. 10D, the stack can be separated, for example, by a further dicing operation along lines 24, into individual optical devices 70.

In each of the optoelectronic modules described above, the lens (e.g., MOE) 18 is disposed so as to intersect a path of the incoming or outgoing light. The MOE 18 is operable to modify one or more characteristics of the light impinging on the MOE. For example, in a light sensing module, the MOE 18 can modify one or more characteristics of the light impinging on the MOE before the light is received and sensed by the image sensor or other light sensor. In some instances, for example, the MOE 18 may focus patterned light onto the light sensor. In some instances, the MOE 18 may split, diffuse and/or polarize the light before it is received and sensed by the light sensor.

Likewise, in a light emitting module, the lens (e.g., MOE) 18 can modify one or more characteristics of the light impinging on the MOE before the light exits the module. Thus, the MOE 18 is operable to modify the light such that modified light is transmitted out of the module. In some cases, the module is operable to produce, for example, one or more of structured light, diffused light, or patterned light. In some instances, the module is operable as a light generating module, e.g., as a structured light projector, a camera flash, a logo projecting module or as a lamp.

Multi-channel modules also can incorporate at least optical device as described above. Such multi-channel modules can include, for example, a light sensor and a light emitter, both of which are mounted, for example, on the same PCB or other substrate. The multi-channel module can include a light emission channel and a light detection channel, which may be optically isolated from one another by a wall that forms part of the module housing.

In some instances, one or more of the modules described above may be integrated into mobile phones, laptops, televisions, wearable devices, or automotive vehicles.

While this specification contains many specifics, these should not be construed as limitations on the scope of the disclosure or of what may be claimed, but rather as descriptions of features specific to particular implementations. Certain features that are described in this specification in the context of separate implementations may also be combined. Conversely, various features that are described in the context of a single implementation may also be implemented in multiple implementations separately or in any suitable sub-combination. Various modifications can be made to the foregoing examples. Accordingly, other implementations also are within the scope of the claims.

1. An apparatus comprising:
an optical aperture defined by a layer of metal disposed on a spacer; and
a lens disposed on a support that is attached to the spacer, the lens being aligned with the optical aperture,
wherein a thickness of the spacer in a region that is between the lens and the optical aperture is less than a thickness of the spacer at its outer periphery.

2. The apparatus of claim 1 wherein the support has a first surface, and a second surface on an opposite side of the support, the first surface being closer to the optical aperture than the second surface, and the lens being disposed on the second surface,
wherein a thickness of the support in a region disposed between the lens and the optical aperture is less than a thickness of the support at its outer periphery.

3. The apparatus of claim 1 wherein the support has a first surface and a second surface on an opposite side of the support, the first surface being closer to the optical aperture than the second surface, and the lens being disposed on the first surface,
wherein a thickness of the support in a region disposed directly below the lens is less than a thickness of the support at its outer periphery.

4. (canceled)

5. (canceled)

6. The apparatus of claim 1, wherein the lens includes a meta-optical element.

7. The apparatus of claim 1, further including:
an active optoelectronic component; and
a lens holder to maintain the lens in place over the active optoelectronic component.

8. An apparatus comprising:
a spacer having an opening extending through the spacer, the opening having a first end that has a first diameter and having a second end that has a second diameter larger than the first diameter, wherein the spacer is composed of a material that is substantially opaque to an application wavelength; and
a lens disposed on a support that is attached to the spacer, the lens being aligned with the opening in the spacer.

9. The apparatus of claim 8 wherein the spacer is composed of a plastic.

10. (canceled)

11. The apparatus of claim 9 wherein the spacer is composed of a semi-crystalline thermoplastic.

12. The apparatus of claim 8, wherein the opening is cone shaped or pyramid shaped.

13. (canceled)

14. The apparatus of claim 8, further including a layer of metal disposed on the spacer and defining an optical aperture.

15. The apparatus of claim 8, wherein the lens includes a meta-optical element.

16. The apparatus of claim 8, wherein an outer perimeter of the spacer has at least one step.

17. (canceled)

18. The apparatus of claim 8, further including:
an active optoelectronic component; and
a lens holder to maintain the lens in place over the active optoelectronic component.

19. An apparatus comprising:
an optical aperture;
a lens disposed on a support and aligned with the optical aperture; and
a spacer separating the lens from the optical aperture,
wherein the spacer has an opening extending from a first end that is closer to the aperture to a second end that is closer to the lens, and
wherein an outer perimeter of the spacer has a plurality of steps.

20. The apparatus of claim 19 wherein an outer diameter of the spacer at a location of a first one of the steps differs from an outer diameter of the spacer at a location of a second one of the steps.

21. The apparatus of claim 19, wherein the spacer is composed of a material that is substantially opaque to an application wavelength.

22. The apparatus of claim 21 wherein the spacer is composed of a plastic.

23. (canceled)

24. (canceled)

25. The apparatus of claim 19, wherein the opening is cone shaped or pyramid shaped.

26. (canceled)

27. The apparatus of claim 19, further including:
an active optoelectronic component; and
a lens holder to maintain the lens in place over the active optoelectronic component,
wherein a first one of the steps at the outer periphery of the spacer is configured so that the spacer is supported by the lens holder.

28. The apparatus of claim 19 wherein a second one of the steps at the periphery of the spacer is configured to allow a gripper to hold the spacer for active alignment with the active optoelectronic component.
